(19) United States
(12) Patent Application Publication
(10) Pub. No.: US 2003/0205770 A1
(43) Pub. Date: Nov. 6, 2003

(54) Mask read only memory device and fabrication method thereof

(76) Inventors: Yao-Wen Chang, Hsinchu (TW); Tao-Cheng Lu, Kaoshiung (TW)

Correspondence Address: J.C.Patents, Inc., Suite 250, 4 Venture, Irvine, CA, 92618, US

(21) Appl. No.: 10/165,632

(22) Filed: Jun. 7, 2002

(30) Foreign Application Priority Data
May 6, 2002 (TW) 91109316

(51) Int. Cl. H01L 29/76

(52) U.S. Cl. 257/390

(57) ABSTRACT

A mask ROM and a fabrication method thereof are described. The method includes forming a buried drain region in the substrate and forming a gate oxide layer on the substrate. A patterned dual-layer structure dielectric layer is formed on the gate oxide layer. A conductive layer, which is perpendicular to the direction of the buried drain region, is then formed on the gate oxide layer and on the dual-layer structure dielectric layer to form a plurality of code memory cells. The code memory cells that comprise the dual-layer structure dielectric layer correspond to the logic state of “0”, while the memory cells that do not comprise the dual-layer structure dielectric layer correspond to the logic state of “1”.

### CROSS-REFERENCE TO RELATED APPLICATION

This application claims the priority benefit of Taiwan application serial no. 91109316, filed May 6, 2002.

### BACKGROUND OF THE INVENTION

1. Field of the Invention

The present invention relates to a memory device and a fabrication method thereof. More particularly, the present invention relates to a mask read only memory (ROM) device and a fabrication method thereof.

2. Background of the Invention

Mask ROM device is a very fundamental type of read-only memory devices, in which a photomask layer is used to define a connection between a metal line and a memory cell or an ion implantation process is used to adjust the threshold voltage to achieve the “on” and “off” of the memory cell. When there are changes in the products of a mask ROM device, no dramatic modification is demanded by the manufacturing process. Only one set of photomask has to be replaced. Therefore, the manufacturing of a mask ROM device is appropriate for mass production. Actually, a part of the manufacturing process can be completed first. The programming of the devices can be quickly performed soon after an order is placed to move up the delivery/shipping date.

FIG. 1A to FIG. 1C are schematic, cross-sectional views illustrating the process flow of the fabrication method of a mask ROM device according to the prior art.

As shown in FIG. 1A, a gate oxide layer 102 is first formed on a surface of a substrate 100 according to the fabrication method of a mask ROM device in the prior art. A gate structure 104 is then formed on the gate oxide layer 102. A buried drain region 106 is further formed in the substrate 100 beside the gate structure 104 as the bit line.

Referring to FIG. 1B, a patterned photoresist layer 108 is formed on the substrate 100, exposing a code implantation channel region 112. Further using the photoresist layer 108 as a mask, a code implantation process 110 is performed to implant coding ions in the code implantation channel region 112.

As shown in FIG. 1C, the photoresist layer 110 is removed. A word line (not shown in Figure) is further used to electrically connect the gate structures 104 that are on a same row. The fabrication for a programmed mask ROM device is thus completed.

In the conventional fabrication process for a mask ROM device, the programming of the memory device includes using a coding mask and a high-energy, high dosage code implantation process. However, if a misalignment occurs between the coding mask and the memory device, the reliability of the device is adversely affected. Moreover, the high-energy, high dosage coding implantation process would increase the resistance of the entire memory device, affecting the characteristics of the device.

Further, as the device dimensions is being scaled down, any micro defects or damages on the memory device will seriously affect the device. In the conventional approach, when a portion of the memory cells in the mask ROM device is damaged, the damaged cells are replaced by a redundancy device. A plurality of redundancy memory cells are formed on the redundancy device to replace the damaged memory cells. However, the redundancy device must be manufactured according to the damages of the memory cells. In other words, the manufacturing and the coding of these redundancy memory cells are made in accordance to the logic state and the relative position of each damaged cells. The manufacturing for a redundancy device of a mask ROM device is thus very time consuming and labor intensive.

### SUMMARY OF THE INVENTION

Accordingly, the present invention provides a mask ROM device and a fabrication method thereof, wherein the problem of misalignment generated during the programming of the memory device is precluded.

The present invention also provides a fabrication method for a mask ROM device, wherein an increase of the device resistance is prevented.

The present invention further provides a fabrication method for a mask ROM device, wherein the redundancy memory cells are formed to replace the damaged memory cell to increase the yield of the memory device.

The present invention further provides a mask ROM device and a fabrication method thereof, wherein the manufacturing of the redundancy device of the mask ROM device is both time and labor efficient.

The present invention further provides a fabrication method for a mask ROM device, wherein a buried drain region is formed in a substrate, and a gate oxide layer is formed on the substrate. A patterned dual-layer structure dielectric layer is then formed on the gate oxide layer, wherein the dual-layer structure dielectric layer includes a patterned silicon oxide-silicon nitride layer. Thereafter, a conductive layer is formed on the gate oxide layer and on the dual-layer structure dielectric layer, perpendicular to the buried drain region to form a plurality of code memory cells. The code memory cells that comprise the dual-layer structure dielectric layer correspond to a memory state of “0”, while the code memory cells that do not comprise the dual-layer structure dielectric layer correspond to a memory state of “1”.

The present invention provides a structure of a mask ROM device, wherein the device comprises a substrate, a buried drain region, a gate oxide layer, a patterned dual-layer dielectric layer and a conductive layer, wherein the buried drain region is located in the substrate and the gate oxide layer is disposed on the surface of the substrate. The patterned dual-layer structure dielectric layer is disposed on the gate oxide layer, wherein the patterned dual-layer structure dielectric layer is a patterned silicon oxide-silicon nitride stacked layer. The conductive layer is perpendicular to the direction of the buried drain region, positioned on the gate oxide layer and the dual-layer structure dielectric layer to form a plurality of code memory cells. The code memory cells that comprise the dual-layer structure dielectric layer correspond to the logic state of “0”, while the cells that do not comprise the dual-layer structure dielectric layer correspond to the logic state of “1”.

The present invention provides a fabrication method for a mask ROM device, wherein a substrate is provided. The substrate comprises a normal device region and a redundancy device region. A buried drain region is formed in the substrate, while a gate oxide layer is formed on the surface of the substrate. A patterned dual-layer dielectric layer is formed on the gate oxide layer, wherein the dual-layer dielectric layer is formed with a patterned silicon oxide-silicon nitride stacked layer. After this, a first conductive layer is formed on the gate oxide layer and the dual-layer dielectric layer in the normal device region, perpendicular to the direction of the buried drain region to form a plurality of code memory cells. The code memory cells that comprise the dual-layer dielectric layer correspond to a logic state of “0”, while the code memory cells that do not comprise the dual-layer dielectric layer correspond to a logic state of “1”. Further, a second conductive layer is formed perpendicular to the direction of the buried drain region and on the gate oxide layer and the dual-layer dielectric layer in the redundancy device region as a plurality of redundancy memory cells. When certain code memory cells in the normal device region are damaged, they are immediately replaced by the redundancy cells in the redundancy device region. Moreover, all the redundancy memory cells comprise a dual-layer dielectric layer, a low voltage erasure method, as in the erasure of a silicon nitride memory device, can be used to code the redundancy memory cells.

The mask ROM device of the present invention includes a substrate that comprises a normal device region and a redundancy device region, a buried drain region, a gate oxide layer, a patterned dual-layer dielectric layer, a first conductive layer and a second conductive layer. The buried drain region is positioned in the substrate, while the gate oxide layer is located on the surface of the substrate. The patterned dual-layer dielectric layer is disposed on the gate oxide layer, wherein the dual-layer dielectric layer includes a patterned silicon oxide-silicon nitride stacked layer. Further, the first conductive layer is disposed on the gate oxide layer and the dual-layer dielectric layer in the normal device region and is perpendicular to the direction of the buried drain region to form a plurality of code memory cells. The code memory cells that comprise the dual-layer dielectric layer corresponds to a logic state of “0”, while the code memory cells that do not comprise the dual-layer dielectric layer corresponds to a logic state of “1”. The second conductive layer is disposed on the gate oxide layer and on the dual-layer dielectric layer in the redundancy device region and is perpendicular to the direction of the buried drain region as a plurality of redundancy memory cells in the redundancy device region. Further, each redundancy memory cell comprises a dual-layer dielectric layer. When certain code memory cells in the normal device region are damaged, they are immediately be replaced by the redundancy cells. Moreover, the redundancy memory cells comprise a dual-layer dielectric layer, a low voltage erasure method, which is similar to the erasure method for a silicon nitride memory device, is used to code the memory cells.

According to the mask ROM device and the fabrication thereof of the present invention, the problem of misalignment in code implantation as in the prior art is prevented.

Further, the mask ROM device and the fabrication thereof of the present invention can prevent an increase of the device's resistance.

Since the redundancy cells of the mask ROM device of the present invention are formed concurrently with the memory cells in the normal device region, the damaged memory cells are replaced immediately to increase the yield of the memory device.

According to the mask ROM device and the fabrication thereof of the present invention, the redundancy cells and the memory cells in the normal device region are formed concurrently, time and labor efficiency is greatly improved.

It is to be understood that both the foregoing general description and the following detailed description are exemplary, and are intended to provide further explanation of the invention as claimed

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A-1C are schematic, cross-sectional views illustrating the process flow of a manufacturing method for a mask ROM device according to the prior art;

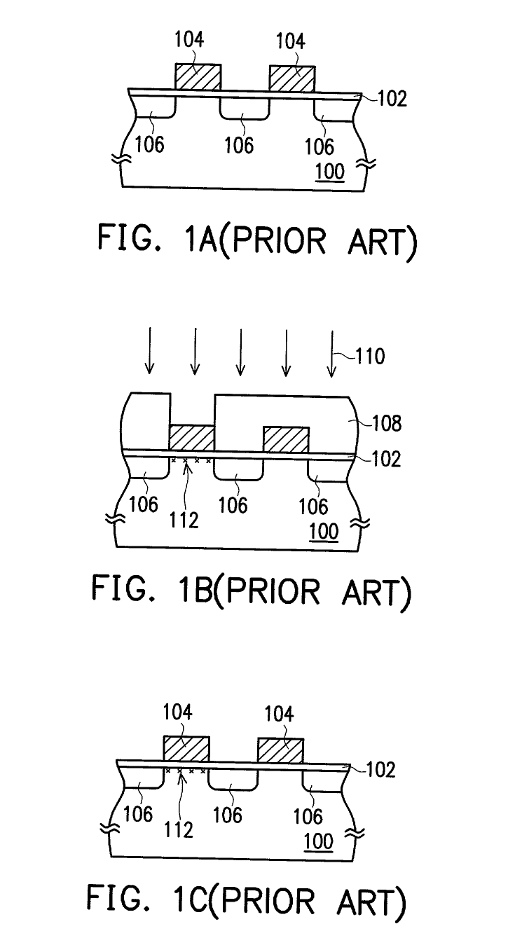

FIGS. 2A-2E are schematic, cross-sectional views illustrating the process flow of a manufacturing method for a mask ROM device according to one preferred embodiment of the present invention;

FIG. 3 is a top view of a mask ROM device that comprises a redundancy region according to one preferred embodiment of the present invention; and

FIG. 4 is a cross-section view of FIG. 3 along the line I-I′.

### DESCRIPTION OF THE PREFERRED EMBODIMENTS

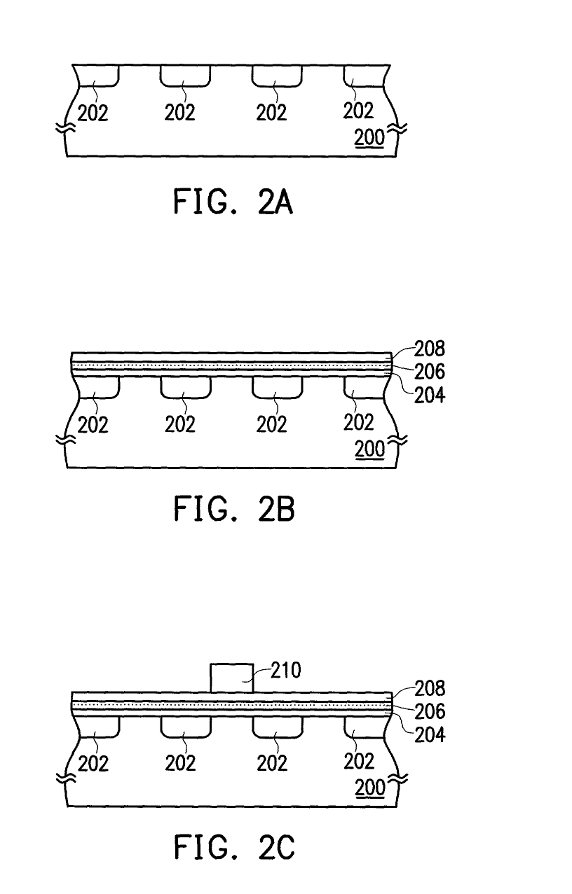

FIGS. 2A-2E are schematic, cross-sectional views illustrating the process flow of a manufacturing method for a mask ROM device according to one preferred embodiment of the present invention.

Referring to FIG. 2A, a buried drain region 202 is formed in a substrate 200 as a bit line. Forming the buried drain region 202 includes forming a patterned photoresist layer (not shown in Figure) on the substrate 200, followed by performing an ion implantation process.

Referring to FIG. 2B, a gate oxide layer 204 is formed on the surface of the substrate 200, wherein the gate oxide layer 204 is about 20 angstroms to about 30 angstroms thick. A silicon nitride layer 206 and a silicon oxide layer 208 are further sequentially formed on the gate oxide layer 204. The silicon nitride layer 206 is about 50 angstroms to 70 angstroms thick, while the silicon oxide layer 208 is about 90 angstroms to about 130 angstroms thick.

Continuing to FIGS. 2C and 2D, a patterned photoresist layer 210 is formed on the silicon oxide layer 208 to pattern the silicon oxide layer 208 and the silicon nitride layer 206. An etching is performed to pattern the silicon oxide layer 208 and the silicon nitride layer 206, forming a dual-layer structure dielectric layer 212. The photoresist layer 210 is subsequently removed.

Thereafter, as shown in FIG. 2E, a conductive layer 214 that is perpendicular to the buried drain region 202 is formed on the gate oxide layer 204 as a plurality of code cells. The code cells that comprise the dual-layer structure dielectric layer 212 correspond to the logic state of “0”, while the code cells that do not comprise the dual-layer structure dielectric layer 212 correspond to the logic state of “1”. The conductive layer 214, which serves as a word line, is made with a material including polysilicon.

The mask ROM device of the present invention relies on a patterned dual-layer structure dielectric layer 212 to program the memory device, rather than relies on a coding mask and a high-energy, high dosage coding implantation process as in the prior art.

The problem of misalignment that may potentially occur between a coding mask and a memory device is thus prevented. Since a high-energy and a high dosage coding implantation process is excluded in the present invention, the problem of an increased resistance in the memory device is also prevented.

The patterned dual-layer structure dielectric layer is used for programming the mask ROM device, which can also be used in the mask ROM device that comprises a redundancy device region.

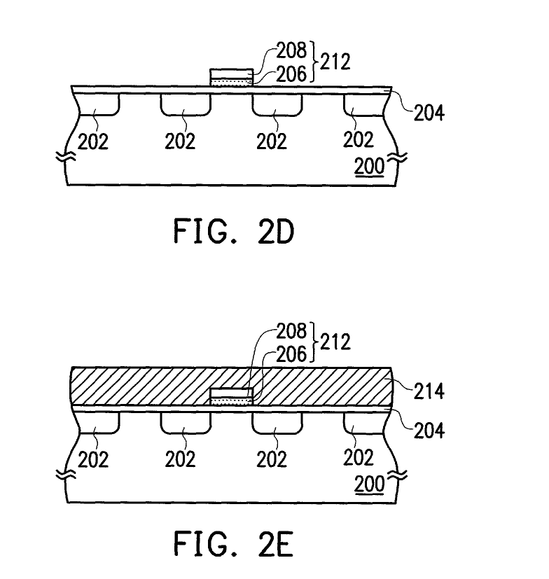

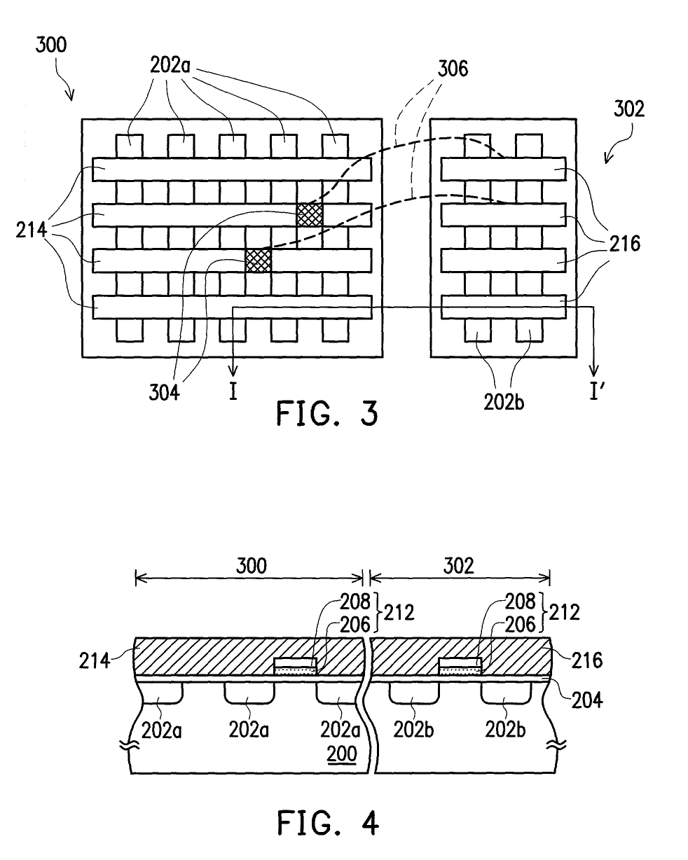

FIG. 3 is a top view of a mask ROM device that comprises a redundancy device region according to one preferred embodiment of the present invention. FIG. 4 is a cross-section view of FIG. 3 along the line I-I′.

Referring to FIGS. 3 & 4 concurrently, a substrate 200 is provided, wherein the substrate 200 comprises an normal device region 300 and a redundancy device region 302. Buried drain regions 202a, 202b are respectively formed in the substrate 200 of the normal device region 300 and the redundancy device region 302. A gate oxide layer 204 is then formed on the substrate 200 of the normal device region 300 and the redundancy device region 302. The gate oxide layer 204 is, for example, 20 angstroms to 30 angstroms thick.

Thereafter, a patterned dual-layer structure dielectric layer 212, wherein the dual-layer structure dielectric layer 212 is formed with a silicon nitride layer 206 and a silicon oxide layer 208.

A first conductive layer 214, which is perpendicular to the direction of the buried drain region 202a, is formed on the gate oxide layer 204 and on the dual-layer structure dielectric layer 212 in the normal device region 300 to form a plurality of code memory cells. The code memory cells that comprises the dual-layer structure dielectric layer 212 corresponds to a logic state of “0”, while those cells that do not comprise the dual-layer structure dielectric layer 212 corresponds to a logic state of “1”. Moreover, the first conductive layer 214 is, for example, a polysilicon layer, and the first conductive layer 214 is served as a word line.

Similarly, a second conductive layer 216, which is perpendicular to the direction of the buried drain region 202b, is formed on the gate oxide layer 204 and the dual-layer structure dielectric layer 212 as the plurality of redundancy cells. Each of the redundancy cell comprises a dual-layer structure dielectric layer 212. The second conductive layer is, for example, a polysilicon layer.

After the fabrication of the memory device is completed, a testing is conducted to determine whether every memory cell in the memory cell is functioning normally. After the testing is completed, if certain cells 304 in the normal cell region 300 are shown to be damaged, they can be replaced by the redundancy cells. Replacing the damaged cells is achieved by a line manufacturing process, wherein a conductive line 306 is used to connect the damaged memory cells 304 and the redundancy cells in the redundancy device region 302. Since every redundancy cell comprises a dual-layer structure dielectric layer, and the gate oxide layer 204 that is under the dual-layer structure dielectric layer is sufficiently thin, the coding of the redundancy memory cells in the redundancy device region 302 is accomplished by a low voltage erasure method, as in the erasure of a silicon nitride memory cell. Therefore, by replacing the damaged memory cells with the redundancy cells in the redundancy device region 302, the yield in the production of the memory device is greatly increased. Further, the redundancy device region 302 and the normal device region 300 are concurrently formed. Moreover, the coding of the redundancy cells in the redundancy device region 302 can be accomplished by the low voltage erasure method as in the erasing of the silicon nitride memory device. The fabrication method for a mask ROM of the present invention is thus more time and labor efficient.

According to the mask ROM device and the fabrication method thereof of the present invention, the problem of misalignment in code implantation as in the prior art is prevented.

The mask ROM device and the fabrication method thereof of the present invention can prevent an increase of the device's resistance.

Since the redundancy cells of the mask ROM device of the present invention are formed concurrently with the memory cells in the normal device region, the damaged memory cells are replaced immediately to increase the yield of the memory device.

According to the mask ROM device and the fabrication method thereof of the present invention, the redundancy cells and the memory cells in the normal device region are formed concurrently, the fabrication method of the mask ROM device of the present invention are thus more time and labor efficient

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method for a mask ROM device, the method comprising:
forming a buried drain region in a substrate;
forming a gate oxide layer on the substrate;
forming a patterned dual-layer structure dielectric layer on the gate oxide layer; and
forming a conductive layer, which is perpendicular to a direction of the buried drain region, on the gate oxide layer and on the dual-layer dielectric layer as a plurality of code memory cells, wherein the code memory cells that comprise the dual-layer structure dielectric layer corresponds to a logic state of “0”, and the code memory cells that do not comprise the dual-layer structure dielectric layer corresponds to a logic state of “1”.

2. The method of claim 1, wherein a lower layer of the dual-layer structure dielectric layer is formed with a material comprises silicon nitride.

3. The method of claim 1, wherein a lower layer of the dual-layer structure dielectric layer is about 50 angstroms to about 70 angstroms thick.

4. The method of claim 1, wherein an upper layer of the dual-layer structure dielectric layer is formed with a material comprises silicon nitride.

5. The method of claim 1, wherein an upper layer of the dual-layer structure dielectric layer is about 90 angstroms to about 130 angstroms thick.

6. The method of claim 1, wherein the gate oxide layer is formed with a thickness of about 20 angstroms to about 30 angstroms.

7. The method of claim 1, wherein the conductive layer is formed with a material comprises polysilicon.

8. A mask ROM device, comprising:
a substrate;
a buried drain region, disposed in the substrate;
a gate oxide layer, positioned on a surface of the substrate;
a patterned dual-layer structure dielectric layer, disposed on the gate oxide layer; and
a conductive layer, located perpendicular to a direction of the buried drain region and on the gate oxide layer and on the dual-layer structure dielectric layer as a plurality of code memory cells, wherein the code memory cells that comprises the dual-layer structure dielectric layer correspond to a logic state of “0” and the code memory cells that do not comprise the dual-layer structure dielectric layer correspond to a logic state of “1”.

9. The device of claim 8, wherein a bottom layer of the dual-layer structure dielectric layer includes silicon nitride.

10. The device of claim 8, wherein a bottom layer of the dual-layer structure dielectric layer is about 50 angstroms to about 70 angstroms thick.

11. The device of claim 8, wherein an upper layer of the dual-layer structure dielectric layer includes silicon oxide.

12. The device of claim 8, wherein an upper layer of the dual-layer structure dielectric layer is about 90 angstroms to about 130 angstroms thick.

13. The device of claim 8, wherein the gate oxide layer is about 20 angstroms to about 30 angstroms thick.

14. The device of claim 8, wherein the conductive layer comprises polysilicon.

15. A fabrication method for a mask ROM device, comprising:
providing a substrate, wherein the substrate comprises a normal device region and a redundancy device region;
forming a buried drain region in the substrate;
forming a gate oxide layer on the substrate;
forming a patterned dual-layer structure dielectric layer on the gate oxide layer;
forming a first conductive layer, which is perpendicular to a direction of the buried drain region, on the gate oxide layer and on the dual-layer structure dielectric layer as a plurality of code memory cells in the normal device region, wherein the code memory cells that comprise the dual-layer structure dielectric layer corresponds to a logic state of “0”, and the code memory cells that do not comprise the dual-layer structure dielectric layer corresponds to a logic state of “1”; and
forming a second conductive layer, which is perpendicular to the direction of the buried drain region, on the gate oxide layer and on the dual-layer structure dielectric layer in the redundancy device region as a plurality of redundancy cells, wherein every redundancy cell comprise the double-layer structure dielectric layer.

16. The method of claim 15, wherein a lower layer of the dual-layer structure dielectric layer is formed with a material containing silicon nitride.

17. The method of claim 15, wherein a lower layer of the dual-layer structure dielectric layer is about 50 angstroms to about 70 angstroms thick.

18. The method of claim 15, wherein an upper layer of the dual-layer structure dielectric layer is formed with a material containing silicon nitride.

19. The method of claim 15, wherein an upper layer of the dual-layer structure dielectric layer is about 90 angstroms to about 130 angstroms thick.

20. The method of claim 15, wherein the gate oxide layer is about 20 angstroms to 30 angstroms thick.

21. The method of claim 15, wherein a material for forming the first conductive layer and the second conductive layer containing polysilicon.

22. A mask ROM device, comprising:
a substrate, wherein the substrate comprises a normal device region and a redundancy device region;
a buried drain region, located in the substrate;
a gate oxide layer, positioned on a surface of the substrate;
a patterned dual-layer structure dielectric layer, disposed on the gate oxide layer;
a first conductive layer, located perpendicular to a direction of the buried drain region and on the gate oxide layer and on the dual-layer structure dielectric layer as a plurality of code memory cells in the normal device region, wherein the code memory cells that comprise the dual-layer structure dielectric layer correspond to a logic state of “0” and the code memory cells that do not comprise the dual-layer structure dielectric layer correspond to a logic state of “1”; and
a second conductive layer, located perpendicular to the direction of the buried drain region and on the gate oxide layer and the dual-layer structure dielectric layer of the redundancy device region as a plurality of redundancy cells, wherein every redundancy cell comprises the dual-layer structure dielectric layer.

23. The device of claim 22, wherein a bottom layer of the dual-layer structure dielectric layer includes silicon nitride.

24. The device of claim 22, wherein a bottom layer of the dual-layer structure dielectric layer is about 50 angstroms to about 70 angstroms thick.

25. The device of claim 22, wherein an upper layer of the dual-layer structure dielectric layer includes silicon oxide.

26. The device of claim 22, wherein an upper layer of the dual-layer structure dielectric layer is about 90 angstroms to about 130 angstroms thick.

27. The device of claim 22, wherein the gate oxide layer is about 20 angstroms to about 30 angstroms thick.

28. The device of claim 22, wherein the first conductive layer and the second conductive layer comprise polysilicon.
